(19) United States
(12) Patent Application Publication
(10) Pub. No.: US 2006/0228479 A1
(43) Pub. Date: Oct. 12, 2006

(54) Bias enhanced nucleation of diamond films in a chemical vapor deposition process

(75) Inventors: Jeremy E. Dahl, Palo Alto, CA (US); Robert M. Carlson, Petaluma, CA (US); Shenggao Liu, Hercules, CA (US); Waqar R. Queshi, San Francisco, CA (US); Wasiq Bokhari, Menlo Park, CA (US)

Correspondence Address: BUCHANAN, INGERSOLL & ROONEY PC, POST OFFICE BOX 1404, ALEXANDRIA, VA, 22313-1404, US

(73) Assignee: Chevron U.S.A. Inc., San Ramon, CA (US)

(21) Appl. No.: 11/386,648

(22) Filed: Mar. 23, 2006

Related U.S. Application Data
(60) Provisional application No. 60/670,472, filed on Apr. 11, 2005.

(51) Int. Cl. C23C 16/26

(52) U.S. Cl. 427/249.8

(57) ABSTRACT

Diamonds are used to nucleate diamond and diamond-like carbon films in a chemical vapor deposition process using bias enhancement. A negative bias is applied to the substrate, such that a cationic form of the diamond is accelerated toward the substrate during the nucleation phase of the deposition. In this manner, the diamondoid may be embedded or partially embedded in the substrate and/or growing film, increasing the adhesion of the film to the substrate. According to the present embodiments, it is not necessary to mechanically pre-seed the substrate for nucleation purposes.

This application claims priority to U.S. Ser. No. 60/670,472, filed Apr. 11, 2005, which is incorporated herein by reference in its entirety

### BACKGROUND OF THE INVENTION

1. Field of the Invention

Embodiments of the present invention are directed in general toward the nucleation of diamond films using diamondoids. Specifically, the present embodiments are directed toward nucleating diamond films in a chemical vapor deposition (CVD) process using bias enhancement.

2. State of the Art

Conventional methods of synthesizing diamond by plasma enhanced chemical vapor deposition (PECVD) techniques are well known in the art, and date back to around the early 1980's. In one method of synthesizing diamond films discussed by A. Erdemir et al. in “Tribology of Diamond, Diamond-Like Carbon, and Related Films,” in Modern Tribology Handbook, Vol. Two, B. Bhushan, Ed. (CRC Press, Boca Raton, 2001) pp. 871-908, a modified microwave CVD reactor is used to deposit a nanocrystalline diamond film using fullerene or methane as a gas carbon precursor.

Diamond films have been nucleated with the lower diamondoids adamantine, diamantine, and triamantane using a chemical vapor deposition process, but these methods did not take advantage bias enhancement used in conjunction with CVD nucleation. What is needed in the art are systems and methods that nucleate diamond films without having to resort to a mechanical diamond pre-seeding.

### SUMMARY OF THE INVENTION

Embodiments of the present invention provide an electrical bias to a substrate (which may be in the form of a DC bias) to enhance the nucleation of a diamond film using lower or higher diamondoids. The diamond and diamond-like carbon films nucleated in such a manner have applications in the optical, electronic, mechanical, chemical, and nuclear industries.

Diamonds are used to nucleate diamond and diamond-like carbon films in a chemical vapor deposition process using bias enhancement. A negative bias is applied to the substrate, such that a cationic form of the diamond is accelerated toward the substrate during the nucleation phase of the deposition. In this manner, the diamondoid may be embedded or partially embedded in the substrate and/or growing film, increasing the adhesion of the film to the substrate. According to the present embodiments, it is not necessary to mechanically pre-seed the substrate for nucleation purposes.

### BRIEF DESCRIPTION OF THE DRAWINGS

FIG. 1 is a schematic of an exemplary chemical vapor deposition reactor that may be used to carry out the present embodiments combining bias enhancement with a CVD process wherein a diamond film is nucleated by diamondoids.

### DETAILED DESCRIPTION OF THE INVENTION

Definition of Diamondoids

The term “diamondoids” refers to substituted and unsubstituted caged compounds of the adamantane series including adamantane, diamantane, triamantane, tetramantane, pentamantane, hexamantane, heptamantane, octamantane, nonamantane, decamantane, undecamantane, and the like, including all isomers and stereoisomers thereof. The compounds have a “diamondoid” topology, which means their carbon atom arrangement is superimposable on a fragment of an FCC diamond lattice. Substituted diamondoids comprise from 1 to 10 and preferably 1 to 4 independently-selected alkyl substituents. Diamondoids include “lower diamondoids” and “higher diamondoids,” as these terms are defined herein, as well as mixtures of any combination of lower and higher diamondoids.

The term “lower diamondoids refers to adamantane, diamantane and triamantane and any and/or all unsubstituted and substituted derivatives of adamantane, diamantane and triamantane. These lower diamondoid components show no isomers or chirality and are readily synthesized, distinguishing them from “higher diamondoids.”

The term “higher diamondoids” refers to any and/or all substituted and unsubstituted tetramantane components; to any and/or all substituted and unsubstituted pentamantane components; to any and/or all substituted and unsubstituted hexamantane components; to any and/or all substituted and unsubstituted heptamantane components; to any and/or all substituted and unsubstituted octamantane components; to any and/or all substituted and unsubstituted nonamantane components; to any and/or all substituted and unsubstituted decamantane components; to any and/or all substituted and unsubstituted undecamantane components; as well as mixtures of the above and isomers and stereoisomers of tetramantane, pentamantane, hexamantane, heptamantane, octamantane, nonamantane, decamantane, and undecamantane.

Adamantane chemistry has been reviewed by Fort, Jr. et al. in “Adamantane: Consequences of the Diamondoid Structure,” Chem. Rev. vol. 64, pp. 277-300 (1964). Adamantane is the smallest member of the diamondoid series and may be thought of as a single cage crystalline subunit. Diamantane contains two subunits, triamantane three, tetramantane four, and so on. While there is only one isomeric form of adamantane, diamantane, and triamantane, there are four different isomers of tetramantane (two of which represent an enantiomeric pair), i.e., four different possible ways of arranging the four adamantane subunits. The number of possible isomers increases non-linearly with each higher member of the diamondoid series, pentamantane, hexamantane, heptamantane, octamantane, nonamantane, decamantane, etc.

Adamantane, which is commercially available, has been studied extensively. The studies have been directed toward a number of areas, such as thermodynamic stability, functionalization, and the properties of adamantane-containing materials. For instance, the following patents discuss materials comprising adamantane subunits: U.S. Pat. No. 3,457,318 teaches the preparation of polymers from alkenyl adamantanes; U.S. Pat. No. 3,832,332 teaches a polyamide polymer forms from alkyladamantane diamine; U.S. Pat. No. 5,017,734 discusses the formation of thermally stable resins from adamantane derivatives; and U.S. Pat. No. 6,235,851 reports the synthesis and polymerization of a variety of adamantane derivatives.

In contrast, the higher diamondoids, have received comparatively little attention in the scientific literature. McKervey et al. have reported the synthesis of anti-tetramantane in low yields using a laborious, multistep process in “Synthetic Approaches to Large Diamondoid Hydrocarbons,” Tetrahedron, vol. 36, pp. 971-992 (1980). To the inventor's knowledge, this is the only higher diamondoid that has been synthesized to date. Lin et al. have suggested the existence of, but did not isolate, tetramantane, pentamantane, and hexamantane in deep petroleum reservoirs in light of mass spectroscopic studies, reported in “Natural Occurrence of Tetramantane (C₂₂H₂₈), Pentamantane (C₂₆H₃₂) and Hexamantane (C₃₀H₃₆) in a Deep Petroleum Reservoir,” Fuel, vol. 74(10), pp. 1512-1521 (1995). The possible presence of tetramantane and pentamantane in pot material after a distillation of a diamondoid-containing feedstock has been discussed by Chen et al. in U.S. Pat. No. 5,414,189.

The four tetramantane structures are iso-tetramantane [1(2)3], anti-tetramantane [121] and two enantiomers of skew-tetramantane [123], with the bracketed nomenclature for these diamondoids in accordance with a convention established by Balaban et al. in “Systematic Classification and Nomenclature of Diamond Hydrocarbons-I,” Tetrahedron vol. 34, pp. 3599-3606 (1978). All four tetramantanes have the formula C₂₂H₂₈ (molecular weight 292). There are ten possible pentamantanes, nine having the molecular formula C₂₆H₃₂ (molecular weight 344) and among these nine, there are three pairs of enantiomers represented generally by [12(1)3], [1234], [1213] with the nine enantiomeric pentamantanes represented by [12(3)4], [1(2,3)4], [1212]. There also exists a pentamantane [1231] represented by the molecular formula C₂₅H₃₀ (molecular weight 330).

Hexamantanes exist in thirty-nine possible structures with twenty eight having the molecular formula C₃₀H₃₆ (molecular weight 396) and of these, six are symmetrical; ten hexamantanes have the molecular formula C₂₉H₃₄ (molecular weight 382) and the remaining hexamantane [12312] has the molecular formula C₂₆H₃₀ (molecular weight 342).

Heptamantanes are postulated to exist in 160 possible structures with 85 having the molecular formula C₃₄H₄₀(molecular weight 448) and of these, seven are achiral, having no enantiomers. Of the remaining heptamantanes 67 have the molecular formula C₃₃H₃₈ (molecular weight 434), six have the molecular formula C₃₂H₃₆ (molecular weight 420) and the remaining two have the molecular formula C₃₀H₃₄ (molecular weight 394).

Octamantanes possess eight of the adamantane subunits and exist with five different molecular weights. Among the octamantanes, 18 have the molecular formula C₃₄H₃₈ (molecular weight 446). Octamantanes also have the molecular formula C₃₈H₄₄ (molecular weight 500); C₃₇H₄₂ (molecular weight 486); C₃₆H₄₀(molecular weight 472), and C₃₃H₃₆ (molecular weight 432).

Nonamantanes exist within six families of different molecular weights having the following molecular formulas: C₄₂H₄₈ (molecular weight 552), C₄₁H₄₆ (molecular weight 538), C₄₀H₄₄ (molecular weight 524, C₃₈H₄₂ (molecular weight 498), C₃₇H₄₀ (molecular weight 484) and C₃₄H₃₆ (molecular weight 444).

Decamantane exists within families of seven different molecular weights. Among the decamantanes, there is a single decamantane having the molecular formula C₃₅H₃₆ (molecular weight 456) which is structurally compact in relation to the other decamantanes. The other decamantane families have the molecular formulas: C₄₆H₅₂ (molecular weight 604); C₄₅H₅₀ (molecular weight 590); C₄₄H₄₈ (molecular weight 576); C₄₂H₄₆ (molecular weight 550); C₄₁H₄₄ (molecular weight 536); and C₃₈H₄₀ (molecular weight 496).

Undecamantane exists within families of eight different molecular weights. Among the undecamantanes there are two undecamantanes having the molecular formula C₃₉H₄₀ (molecular weight 508) which are structurally compact in relation to the other undecamantanes. The other undecamantane families have the molecular formulas C₄₁H₄₂ (molecular weight 534); C₄₂H₄₄ (molecular weight 548); C₄₅H₄₈ (molecular weight 588); C₄₆H₅₀ (molecular weight 602); C₄₈H₅₂ (molecular weight 628); C₄₉H₅₄ (molecular weight 642); and C₅₀H₅₆ (molecular weight 656).

The CVD Reactor

Diamondoids may be used to nucleate a diamond film in a CVD reactor in a variety of ways. The diamondoids may be applied to the surface of the substrate before the substrate is inserted into the reactor. Alternatively, the diamondoids may be sublimed into the gas phase such that they to may be introduced to a CVD reactor either prior to or during a deposition.

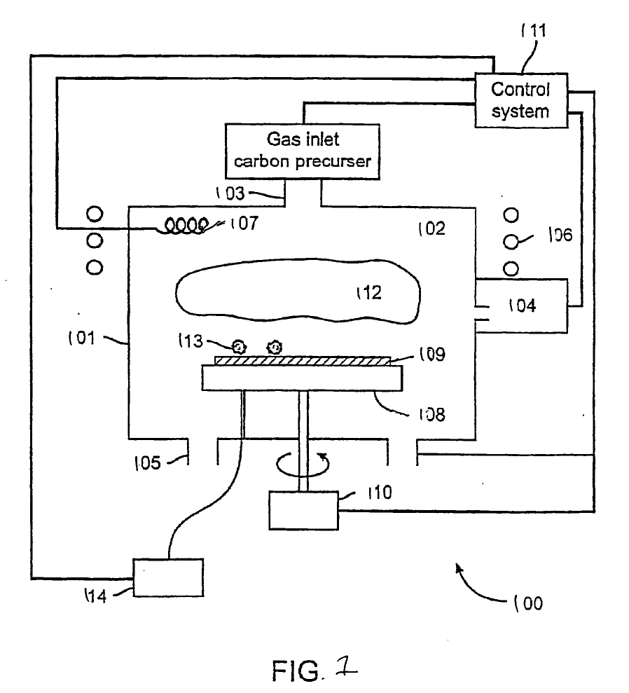

An exemplary CVD reactor that may be used to carry out the present embodiments is shown in FIG. 1. A reactor 100 comprises reactor walls 101 enclosing a process space 102. A gas inlet tube 103 is used to introduce process gas into the process space 102, the process gas comprising methane, hydrogen, and optionally an inert gas such as argon. A diamondoid subliming or volatilizing device 104 may be used to volatilize and inject a diamondoid containing gas into the reactor 100. The volatilizer 104 may include a means for introducing a carrier gas such as hydrogen, nitrogen, argon, or an inert gas such as a noble gas other than argon, and it may contain other carbon precursor gases such as methane, ethane, or ethylene.

Consistent with conventional CVD reactors, the reactor 100 may have exhaust outlets 105 for removing process gases from the process space 102; an energy source for coupling energy into process space 102 (and striking a plasma from) process gases contained within process space 102; a filament 107 for converting molecular hydrogen to monoatomic hydrogen; a susceptor 108 onto which a diamondoid containing film 109 is grown; a means 110 for rotating the susceptor 108 for enhancing the sp³-hybridized uniformity of the diamondoid-containing film 109; and a control system 111 for regulating and controlling the flow of gases through inlet 103, the amount of power coupled from source 106 into the processing space 102; and the amount of diamondoids injected into the processing space 102 the amount of process gases exhausted through exhaust ports 105; the atomization of hydrogen from filament 107; and the means 110 for rotating the susceptor 108. In an exemplary embodiment, the plasma energy source 106 comprises an induction coil such that power is coupled into process gases within processing space 102 to create a plasma 112. The frequency of the power coupled to the plasma may be in the microwave range, and in one embodiment ranges from about 900 MHz to 2.5 GHz.

A diamondoid nucleating agent may be injected into reactor 400 according to embodiments of the present invention through the volatilizer 404, which serves to volatilize the diamondoids. The diamondoid nucleating agent may be either a lower diamondoid, higher diamondoid, or combination of a lower and higher diamondoid when used in this bias enhanced process. A carrier gas such as methane or argon may be used to facilitate transfer of the diamondoids entrained in the carrier gas into the process space 102. The injection of such diamondoids may facilitate growth of a CVD grown diamond film 109 by allowing carbon atoms to be deposited at a rate of about 10 to 100 or more at a time, unlike conventional plasma CVD diamond techniques in which carbons are added to the growing film one atom at a time. Growth rates may be increased by at least two to three times and in some embodiments, growth rates may be increased by at least an order of magnitude. In some embodiments, the carrier gas is substantially free of nitrogen.

Diamondoids may act as carbon precursors for a CVD diamond film, meaning that each of the carbons of the diamondoids injected into processing space 102 are added to the diamond film in a substantially intact form. In addition to this role, diamondoids 113 injected into the reactor 100 from the volatilizer 104 may serve merely to nucleate a CVD diamond film grown according to conventional techniques. In such a case, the diamondoids 113 are entrained in a carrier gas, the latter which may comprise methane, hydrogen, and/or argon, and injected into the reactor 100 at the beginning of a deposition process to nucleate a diamond film that will grow from methane as a carbon precursor (and not diamondoid) in subsequent steps. In some embodiments, the selection of the particular isomer of a particular diamondoid may facilitate the growth of a diamond film having a desired crystalline orientation that may have been difficult to achieve under conventional circumstances. Alternatively, the introduction of a diamondoid nucleating agent into reactor 100 from volatilizer 104 may be used to facilitate an ultracrystalline morphology into the growing film for the purposes discussed above.

The electrical bias may be applied to the substrate 109 via a substrate controller shown by reference numeral 114 in FIG. 1. The substrate controller 114 may include an electrical supply for providing the bias to the substrate. The electrical bias is a DC (direct current) bias in one embodiment, and may range from about −100 to −300 volts relative to a bias ring or other unit located within the plasma above the substrate. In alternative embodiments, the DC bias has a value of from about −100 to about −200 volts.

The substrate controller 114 may also contain a means for heating the substrate 109, or the gases in the reactor may be heated by some other means. In one embodiment, the temperature of the gases being used to carry out the deposition range from about 400 to 850° C.

Nucleation with Bias Enhanced CVD

Currently, CVD nucleation is achieved by abrading or scratching the surface of a substrate with fine-grain diamond particulates prior to initiating the CVD process. Commonly used substrates in such a process are polished silicon wafers, where the diamond particulates in this abrading technique embed into the silicon. The diamond fragments may have a size distribution in a range of tens of nanometers.

The present embodiments offer improvements to techniques used in the past by providing bias enhanced CVD to produce diamond films (and/or diamond-like carbon films) having excellent adhesion to the substrate, and, when desired, a predetermined crystallographic orientation of the growing film. While not wishing to be bound by any particular theory, it is suggested that diamondoids offer the potential to function as a nucleating species in a bias enhanced process because they can be ionized to form cations with superior stability relative to other sp³ hybridized carbon species of comparable carbon number. Such cation stability is demonstrated by the negligible fragmentation of charged diamondoid species studied by mass spectroscopy and reported by R. J. Waltman and A. C. Ling in an article titled “Mass spectrometry of diamantane and some adamantane derivatives,” Canadian Journal of Chemistry 58(20), pp. 2189-95 (1980). It is this stability of the positively charged diamondoid species that enables their use in a bias enhanced CVD process.

According to present bias enhanced embodiments, the positively charged “molecular ions” of the diamondoid nucleating species may be accelerated intact toward a surface or a substrate by applying a negative potential to the substrate during the film deposition process.

Deposition parameters which may be controlled during the nucleation and growth phase are feed gas composition, power coupled to the plasma (in the case of plasma enhanced CVD), bias voltage applied to the substrate, and substrate temperature. By applying a negative bias voltage to the substrate, and thereby accelerating the positively charged diamondoid species toward its surface, the diamond nuclei may be deposited, and to some degree implanted, onto or into the surface of the substrate.

Doping of the nucleated film is also possible when using the present techniques. Diamond (and diamond-like carbon films) may be nucleated with heteroatom containing diamondoids, such that the nucleated film contains either an electron-donating species for the creation of an n-type diamond film, or an electron-withdrawing species, to make a p-type diamond film.

It is contemplated that multiple layers of diamond or diamond-like materials may be deposited in this manner. A first layer may be deposited by chemical vapor deposition using a first set of deposition conditions, and then a second layer deposited using a second set of deposition conditions. Various layers may be deposited with or without doping.

The weight of diamondoids and substituted diamondoids, as a function of the total weight of the CVD film (where the weight of the diamondoid functional groups are included in the diamondoid portion), may in one embodiment range from about 0.001 to 99.9 percent by weight. In another embodiment, the content of diamondoids and substituted diamondoids is about 10 to 99 percent by weight. In another embodiment, the proportion of diamondoids and substituted diamondoids in the CVD film relative to the total weight of the film is about 25 to 95 percent by weight.

The negative substrate bias in the presence of the nucleating diamondoids promotes excellent diamond nucleation without the use of a mechanical diamond pre-seeding. The present bias enhanced, diamondoid nucleated process produces diamond layers having excellent properties, even approaching those of perfect diamond crystals. This is particularly true of films grown on silicon wafer substrates for microelectronic applications. The present methods provide high densities of diamond nuclei, high film forming speeds, and high adhesion of the film to the substrate.

Many modifications of the exemplary embodiments of the invention disclosed above will readily occur to those skilled in the art. Accordingly, the invention is to be construed as including all structure and methods that fall within the scope of the appended claims.

What is claimed is:

1. A method of nucleating a diamond film with a diamondoid, the method comprising:
applying an electrical bias to a substrate in a chemical vapor deposition reactor;
converting the diamondoid to a charged species; and
accelerating the charged diamondoid species toward the electrically biased substrate.

2. The method of claim 1, wherein the electrical bias on the substrate is a negatively charged bias.

3. The method of claim 2, wherein the negatively charged bias on the substrate ranges from about −100 to about −300 volts.

4. The method of claim 1, wherein the charged diamondoid species is a cationic species.

5. The method of claim 1, wherein the diamondoid is selected from the group consisting of adamantane, diamantine, and triamantane.

6. The method of claim 1, wherein the diamondoid is selected from the group consisting of a tetramantane, a pentamantane, a hexamantane, a heptamantane, an octamantane, a nonamantane, a decamantane, and an undecamantane.
